(19) United States
(12) Patent Application Publication
(10) Pub. No.: US 2025/0287797 A1
(43) Pub. Date: Sep. 11, 2025

(54) DISPLAY PANEL, DISPLAY DEVICE, AND METHOD OF MANUFACTURING THE SAME

(71) Applicant: Samsung Display Co., Ltd., Yongin-si (KR)

(72) Inventors: EUNBYUL KIM, Yongin-si (KR); HANBUM KWON, Yongin-si (KR); YOUNGMIN AHN, Yongin-si (KR); DAEHWAN JANG, Yongin-si (KR)

(73) Assignee: Samsung Display Co., Ltd., Yongin-si (KR)

(21) Appl. No.: 19/062,610

(22) Filed: Feb. 25, 2025

(30) Foreign Application Priority Data
Mar. 8, 2024 (KR) 10-2024-0033351

(51) Int. Cl. H10K 59/131; H10K 59/12; H10K 59/80

(52) U.S. Cl. CPC H10K 59/131; H10K 59/1201; H10K 59/8722

(57) ABSTRACT

Provided is a display panel including a pixel, a signal line electrically connected to the pixel, and a signal pad electrically connected to the signal line, wherein the signal pad includes a first conductive pattern electrically connected to an end portion of the signal line, a second conductive pattern including a first layer disposed on the first conductive pattern, a second layer disposed on the first layer, and a third layer disposed on the second layer, and an insulating pattern disposed between the first conductive pattern and the second conductive pattern, and a groove pattern is formed on an upper surface of the second conductive pattern.

### CROSS-REFERENCE TO RELATED APPLICATION(S)

This application claims priority and the benefits of Korean Patent Application No. 10-2024-0033351 under 35 U.S.C. § 119, filed on Mar. 8, 2024, in the Korean Intellectual Property Office, the entire contents of which are incorporated herein by reference.

### BACKGROUND

### 1. Technical Field

The disclosure generally relates to a display panel, a display device, and a method of manufacturing the same, and more particularly to, a display panel including a pad area, a display device, and a method of manufacturing the display device.

### 2. Description of the Related Art

A display device may include a display area that is activated according to an electrical signal. The display device may sense an input applied from an external unit through the display area, at the same time, display various images, and thus provide information to a user.

The display device may include a display panel and a circuit board. The display panel may be electrically connected to a main board through the circuit board. A driving chip may be mounted on the display panel.

### SUMMARY

Embodiments of the disclosure provide a display panel capable of improving bonding reliability, a display device, and a method of manufacturing the same.

According to an embodiment, a display panel includes a pixel, a signal line electrically connected to the pixel, and a signal pad electrically connected to the signal line, wherein the signal pad includes a first conductive pattern electrically connected to an end portion of the signal line, a second conductive pattern including a first layer disposed on the first conductive pattern, a second layer disposed on the first layer, and a third layer disposed on the second layer, and an insulating pattern disposed between the first conductive pattern and the second conductive pattern, and a groove pattern is formed on an upper surface of the second conductive pattern.

The insulating pattern may be disposed inside the first conductive pattern and the second conductive pattern in a plan view.

The insulating pattern may include a lower surface adjacent to the first conductive pattern, an upper surface opposite to the lower surface and spaced apart from the first conductive pattern, and a side surface connected to the upper surface and the lower surface, and the second conductive pattern may cover a portion of the first conductive pattern, in which the insulating pattern is not disposed, the upper surface of the insulating pattern, and the side surface of the insulating pattern.

The groove pattern may overlap the upper surface of the insulating pattern in a plan view.

The groove pattern may be formed through the third layer and expose the second

layer.

The second conductive pattern may further include an oxide film disposed on the third layer, and the groove pattern may be formed through the oxide film.

The groove pattern may include at least one groove or at least one crack.

A thickness of the second layer may be greater than each of a thickness of the first layer and a thickness of the third layer in a thickness direction.

A conductivity of the second layer may be greater than each of a conductivity of the first layer and a conductivity of the third layer.

The insulating pattern may include a polymer.

According to an embodiment, a display device includes a display panel including a signal pad, an electronic component electrically connected to the display panel, and an adhesive layer that bonds the display panel and the electronic component together, wherein the signal pad includes a first conductive pattern, a second conductive pattern in which a groove pattern is formed on an upper surface of the second conductive pattern and which is disposed on the first conductive pattern, and an insulating pattern disposed between the first conductive pattern and the second conductive pattern.

The second conductive pattern may include a first layer disposed on the first conductive pattern, a second layer disposed on the first layer, and a third layer disposed on the second layer, and the groove pattern may penetrate the third layer and expose the second layer.

The electronic component may include a substrate and a bump electrode disposed on the substrate and protruding in a thickness direction, and the bump electrode may be in contact with the second layer and fills the groove pattern.

The second layer exposed by the groove pattern may be covered by the bump electrode and may not be in contact with the adhesive layer.

The insulating pattern may be disposed inside the first conductive pattern and the second conductive pattern in a plan view.

The insulating pattern may include an upper surface spaced apart from the first conductive pattern, and the groove pattern may overlap the upper surface of the insulating pattern in a plan view.

The insulating pattern may include a polymer.

According to an embodiment, a method of manufacturing a display device includes providing a preliminary signal pad including a first conductive pattern electrically connected to a signal line, a second conductive pattern disposed on the first conductive pattern, and an insulating pattern disposed between the first conductive pattern and the second conductive pattern, and providing a signal pad by forming a groove pattern on an upper surface of the second conductive pattern.

The second conductive pattern may include a first layer disposed on the first conductive pattern, a second layer disposed on the first layer, and a third layer disposed on the second layer, and the groove pattern may be formed by a laser or a needle to penetrate the third layer and expose the second layer.

The method may further include bonding an electronic component including a bump electrode immediately after the providing of the signal pad, wherein the bump electrode may be bonded to be in contact with the second layer exposed by the groove pattern.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment of the disclosure.

FIGS. 2A and 2B are exploded schematic perspective views of the display device according to an embodiment of the disclosure.

FIG. 3 is a schematic cross-sectional view of a display module according to an embodiment of the disclosure.

FIG. 4 is a schematic plan view of a display panel according to an embodiment of the disclosure.

FIG. 5 is a cross-sectional view of the display panel, which illustrates a pixel, according to an embodiment of the disclosure.

FIG. 6 is an enlarged schematic perspective view of a pad area of the display device according to an embodiment of the disclosure.

FIG. 7A is a schematic plan view of the pad area according to an embodiment of the disclosure.

FIGS. 7B and 7C are schematic cross-sectional views of pad areas PA1 and PA2 according to an embodiment of the disclosure.

FIG. 8 is a schematic cross-sectional view illustrating a bonding structure of the display device according to an embodiment of the disclosure.

FIGS. 9 to 11D are schematic cross-sectional views illustrating one operation of a method of manufacturing the display device according to an embodiment of the disclosure.

FIGS. 12A to 12D are schematic plan views of a pad area according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

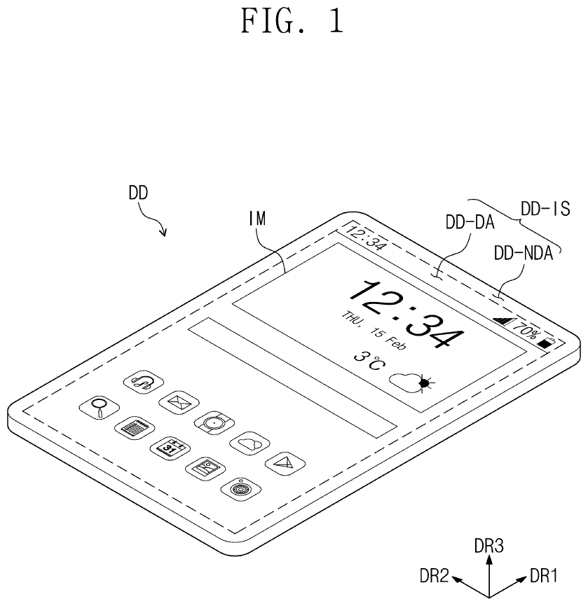

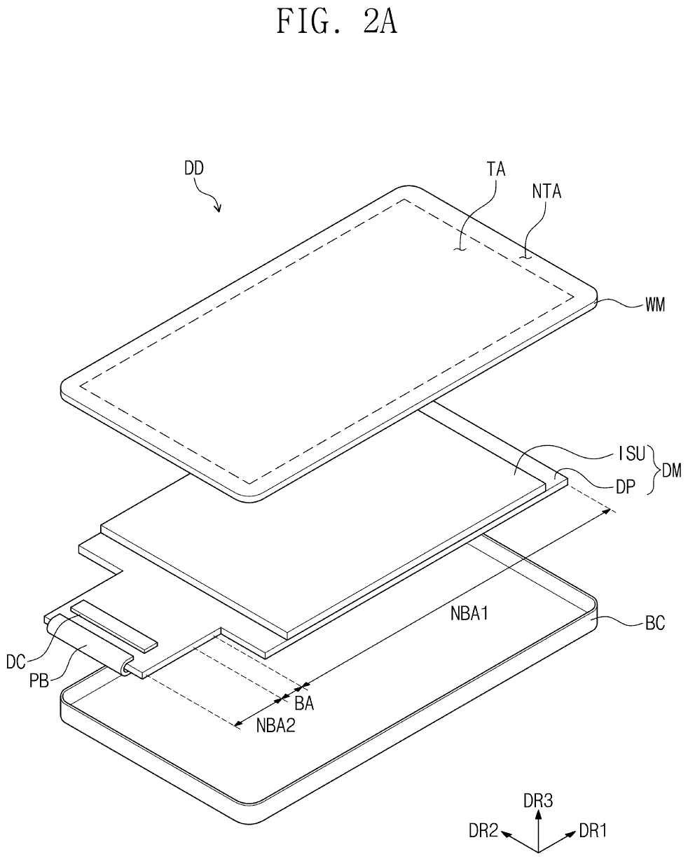

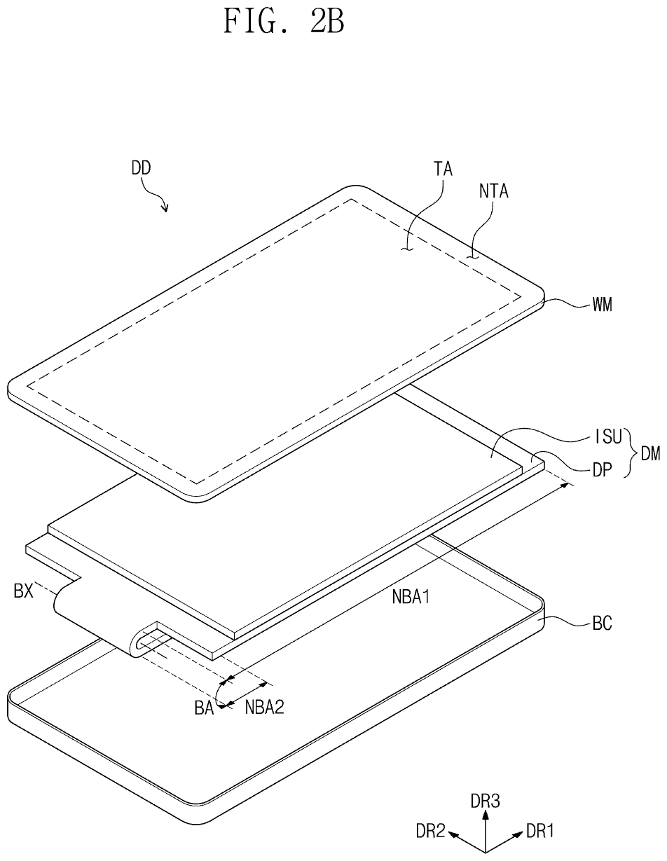

FIG. 1 is a schematic perspective view of a display device DD according to an embodiment of the disclosure. FIGS. 2A and 2B are exploded schematic perspective views of the display device DD according to an embodiment of the disclosure. FIG. 2B illustrates the display device DD in a state in which a bending area BA illustrated in FIG. 2A is bent.

Referring to FIG. 1, the display device DD is illustrated as a mobile phone terminal. The display device DD according to the disclosure may be applied to small and medium-sized electronic devices such as tablets, vehicle navigation systems, game consoles, and smart watches as well as large-sized electronic devices such as televisions and monitors.

The display device DD may have a rectangular shape having long sides extending in a first direction DR1 and short sides extending in a second direction DR2 intersecting the first direction DR1 in a plan view. However, the disclosure is not limited thereto. In other embodiment, the display device DD may have a rectangular shape having long sides extending in the second direction DR2 and short sides extending in the first direction DR1. The display device DD may have various shapes such as a circle and a polygon in a plan view.

Hereinafter, a direction substantially perpendicular to a plane defined by the first direction DR1 and the second direction DR2 is defined as a third direction DR3. In the specification, the wording “in a plan view” means a state viewed from the third direction DR3.

The display device DD may be rigid or flexible. The wording “flexible” may mean a property that may be bent and include both a structure that is completely folded and a structure that may be bent by several nanometers. For example, the flexible display device DD may include a curved display device, a rollable display device, and a foldable display device.

The display device DD may display an image IM through a display surface DD-IS. Icon images are illustrated as examples of the image IM. The display surface DD-IS may be parallel to a plane defined by the first direction DR1 and the second direction DR2.

The display surface DD-IS may include a display area DD-DA that displays the image IM and a non-display area DD-NDA adjacent to the display area DD-DA. The non-display area DD-NDA may be an area that does not display an image. However, the disclosure is not limited thereto, and the non-display area DD-NDA may be adjacent to one side of the display area DD-DA or may be omitted.

Referring to FIGS. 2A and 2B, the display device DD may include a window WM, a display module DM, and a storage member BC.

The window WM may be disposed on the display module DM and transmit an image provided from the display module DM to an outside. Although not illustrated, the window WM may include a base layer and functional layers arranged on the base layer. The functional layers may include a protective layer, a fingerprint preventing layer, and the like. The base layer of the window WM may be made of glass, sapphire, or plastic. The base layer of the window WM may include an optically transparent insulating material. For example, the base layer of the window WM may include a glass or plastic film or may include a glass substrate and a plastic film bonded by an adhesive.

The window WM may include a transmissive area TA and a non-transmissive area NTA. The transmissive area TA may overlap the display area DD-DA illustrated in FIG. 1 and have a shape corresponding to the display area DD-DA. The non-transmissive area NTA may overlap the non-display area DD-NDA illustrated in FIG. 1 and have a shape corresponding to the non-display area DD-NDA. The non-transmissive area NTA may be an area having relatively low light transmittance compared to the transmissive area TA. The non-transmissive area NTA may be defined by a bezel pattern in a partial area of the base layer of the window WM, and an area in which the bezel pattern is not disposed may be defined as the transmissive area TA. However, the disclosure is not limited thereto, and the non-transmissive area NTA may be omitted.

Although not illustrated, a reflection preventing layer may be disposed between the window WM and the display module DM. The reflection preventing layer may reduce reflectance of an external light input from the outside of the display device DD. The reflection preventing layer may include color filters. The color filters may have a predetermined arrangement. For example, the color filters may be arranged in consideration of light emitting colors of pixels included in a display panel DP, which will be described below. The reflection preventing layer may further include a black matrix adjacent to the color filters.

According to an embodiment of the disclosure, the display module DM may include the display panel DP and an input sensor ISU disposed on the display panel DP.

The display panel DP may be one of a liquid crystal display panel, an electrophoretic display panel, a microelectromechanical system display panel, an electrowetting display panel, an organic light emitting display panel, an inorganic light emitting display panel, and a quantum dot light emitting display panel. However, the disclosure is not particularly limited thereto. Hereinafter, the display panel DP will be described as an organic light emitting display panel.

The input sensor ISU may include any one of a capacitive sensor, an optical sensor, an ultrasonic sensor, and an electromagnetic induction sensor. The input sensor ISU may be disposed on the display panel DP through a continuous process or may be separately manufactured and then attached to an upper portion of the display panel DP through an adhesive layer, and the disclosure is not limited to an embodiment.

The display device DD may further include a driving chip DC disposed on the display panel DP. The display device DD may further include a circuit board PB disposed on the display panel DP. The circuit board PB may be a flexible circuit board, but the disclosure is not limited thereto. For example, the circuit board PB may be rigid. The circuit board PB may electrically connect the display panel DP and a main circuit board.

The driving chip DC may include driving elements, for example, a data driving circuit, for driving pixels of the display panel DP. Although a structure in which the driving chip DC is mounted on the display panel DP is illustrated in FIG. 2A, the disclosure is not limited thereto. For example, the driving chip DC may be mounted on the circuit board PB. The driving chip DC mounted (e.g., directly mounted) on the display panel DP and the circuit board PB may be collectively referred to as electronic components.

The display panel DP may include the bending area BA and a first non-bending area NBA1 and a second non-bending area NBA2 spaced apart from each other in the first direction DR1 with the bending area BA interposed therebetween.

The bending area BA may be defined as an area in which the display panel DP is bent along a virtual bending axis BX extending in the second direction DR2. The first non-bending area NBA1 may be defined as an area overlapping the transmissive area TA, and the second non-bending area NBA2 may be defined as an area to which the circuit board PB is electrically connected. In case that the bending area BA is bent about with respect to the bending axis BX, the circuit board PB and the driving chip DC may be bent in a direction toward a rear surface of the display panel DP and arranged under the rear surface of the display panel DP. Although not illustrated, additional components may be arranged to compensate for a step difference between the circuit board PB and the rear surface of the display panel DP, which are formed by the bending area BA.

A width of the first non-bending area NBA1 in the second direction DR2 may be greater than widths of the bending area BA and the second non-bending area NBA2. However, the disclosure is not limited thereto. A width of the bending area BA in the second direction DR2 may be provided in a shape that becomes narrower from the first non-bending area NBA1 to the second non-bending area NBA2. The disclosure is not limited to an embodiment.

As illustrated in FIG. 2B, as a portion of the display panel DP is bent, the circuit board PB electrically bonded to the display panel DP may be disposed on the rear surface of the display panel DP.

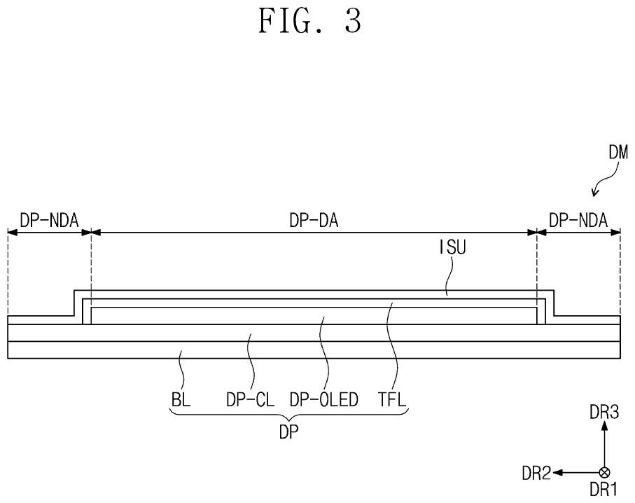

The storage member BC may accommodate the display module DM and may be coupled to the window WM. The circuit board PB may be disposed at one end of the display panel DP and may be electrically connected to a circuit element layer DP-CL, which will be described in FIG. 3. Although not illustrated, the display device DD may further include a main board, electronic modules mounted on the main board, a camera module, a power module, and the like.

Although the mobile phone terminal has been described as an example of the display device DD, but in the specification, it is sufficient for the display device DD to include two or more bonded electronic components. The display panel DP and the driving chip DC mounted on the display panel DP may correspond to different electronic components, and only the display panel DP and the driving chip DC may constitute the display device DD. The display panel DP and the circuit board PB electrically connected to the display panel DP may correspond to different electronic components, and only the display panel DP and the circuit board PB may constitute the display device DD. Further, only the main board and the electronic modules mounted on the main board may constitute the display device DD. Hereinafter, the display device DD according to the disclosure will be described while focusing on a bonding structure of the display panel DP and the driving chip DC mounted on the display panel DP.

FIG. 3 is a schematic cross-sectional view of the display module DM according to an embodiment of the disclosure.

Referring to FIG. 3, the display panel DP may include a base layer BL, the circuit element layer DP-CL, a display element layer DP-OLED, and an upper insulating layer TFL. The input sensor ISU may be disposed on the upper insulating layer TFL.

The display panel DP may include a display area DP-DA and a non-display area DP-NDA. The display area DP-DA of the display panel DP may overlap the display area DD-DA illustrated in FIG. 1 or the transmissive area TA illustrated in FIG. 2A, and the non-display area DP-NDA may overlap the non-display area DD-NDA illustrated in FIG. 1 or the non-transmissive area NTA illustrated in FIG. 2A.

The base layer BL may include at least one plastic film. The base layer BL is a flexible substrate and may include a plastic substrate, a glass substrate, a metal substrate, or an organic/inorganic composite material substrate.

The circuit element layer DP-CL may include at least one intermediate insulating layer and a circuit element. The intermediate insulating layer may include at least one intermediate inorganic layer and at least one intermediate organic layer. The circuit element may include signal lines, a driving circuit of the pixel, and the like. An insulating layer, a semiconductor layer, and a conductive layer are formed by a process such as coating and deposition. Thereafter, the insulating layer, the semiconductor layer, and the conductive layer may be selectively patterned through photolithography and etching processes. A semiconductor pattern, a conductive pattern, the signal line or the like are formed through these processes. The patterns arranged on the same layer are formed through the same process. Hereinafter, the fact that the patterns are formed through the same process means that the patterns contain the same material and have the same laminated structure.

The display element layer DP-OLED may include multiple light emitting elements. The display element layer DP-OLED may further include an organic layer such as a pixel defining film.

The upper insulating layer TFL may seal the display element layer DP-OLED. The upper insulating layer TFL may be disposed on the display element layer DP-OLED. The upper insulating layer TFL may overlap the display area DP-DA and the non-display area DP-NDA. The upper insulating layer TFL may overlap at least a portion of the non-display area DP-NDA. For example, the upper insulating layer TFL may include a thin film encapsulation layer. The thin film encapsulation layer may include a laminated structure of an inorganic layer, an organic layer, and an inorganic layer. The upper insulating layer TFL may protect the display element layer DP-OLED from foreign substances such as moisture, oxygen, and dust particles. However, the disclosure is not limited thereto, and the upper insulating layer TFL may further include an additional insulating layer in addition to the thin film encapsulation layer. For example, the upper insulating layer TFL may further include an optical insulating layer for controlling a refractive index.

An encapsulation substrate may be provided instead of the upper insulating layer TFL. For example, the encapsulation substrate may face the base layer BL, and the circuit element layer DP-CL and the display element layer DP-OLED may be arranged between the encapsulation substrate and the base layer BL.

The input sensor ISU may be directly disposed on the display panel DP. Hereinafter, “component A is directly disposed on component B” means that no separate layer is disposed between component A and component B. The input sensor ISU together with the display panel DP may be manufactured by a continuous process. However, the manufacturing process of the disclosure is not limited thereto, and the input sensor ISU may be provided as an individual panel and coupled to the display panel DP through an adhesive layer. In other embodiments, the input sensor ISU may be omitted.

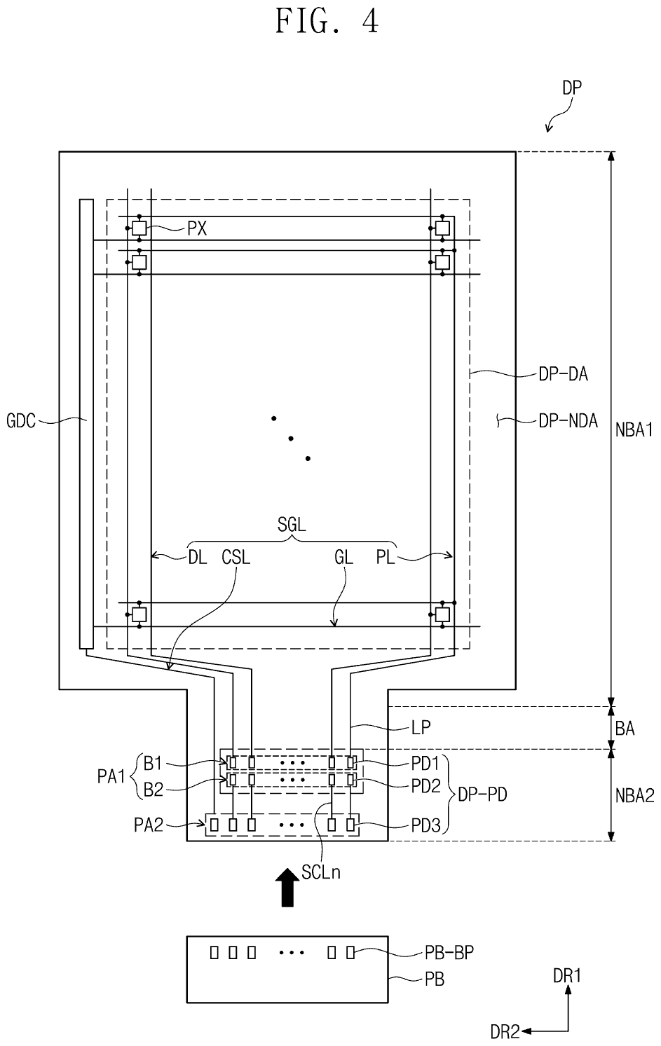

FIG. 4 is a schematic plan view of the display panel DP according to an embodiment of the disclosure.

Referring to FIG. 4, the display panel DP may include multiple pixels PX, a gate driving circuit GDC, multiple signal lines SGL, and multiple signal pads DP-PD.

The pixels PX may be arranged in the display area DP-DA. Each of the pixels PX includes a light emitting element and a pixel driving circuit electrically connected thereto. The light emitting element may be an organic light emitting device. The gate driving circuit GDC may sequentially output gate signals to multiple gate lines GL, which will be described below. A transistor of the gate driving circuit GDC may be formed through the same process as that of a transistor of the pixel PX, for example, a low temperature polycrystaline silicon (LTPS) process or a low temperature polycrystalline oxide (LTPO) process. The display panel DP may further include another driving circuit that provides light emitting control signals to the pixels PX.

The signal lines SGL may include the gate lines GL, data lines DL, a power line PL, and a control signal line CSL. The gate lines GL, the data lines DL, and the power line PL may be electrically connected to each of the pixels PX. The control signal line CSL may provide a control signal to a scan driving circuit.

The signal lines SGL may overlap the display area DP-DA and the non-display area DP-NDA. Each of the signal lines SGL may include a wiring line part LP. Although not illustrated, the signal lines SGL may further include a pad part. The wiring line part LP may overlap the display area DP-DA and the non-display area DP-NDA. The pad part may be electrically connected to a distal end of the wiring line part LP.

Multiple signal pads DP-PD may include first pads PD1, second pads PD2, and third pads PD3. An area in which the first and second pads PD1 and PD2 are arranged may be defined as a first pad area PA1, and an area in which the third pads PD3 are arranged may be defined as a second pad area PA2.

The first pad area PA1 may be an area overlapping the driving chip DC of FIG. 2A, and the second pad area PA2 may be an area overlapping the circuit board PB. The first pad area PA1 may include a first area B1 in which the first pads PD1 are arranged and a second area B2 in which the second pads PD2 are arranged. The first pad area PA1 and the second pad area PA2 may be arranged in the non-display area DP-NDA. The first pad area PA1 and the second pad area PA2 may be spaced apart from each other in the first direction DR1. It is illustrated that one pad row is disposed in the first pad area PA1, but the disclosure is not limited thereto, and multiple pad rows may be arranged in the first pad area PA1.

Each of the first pads PD1 may be electrically connected to a corresponding data line DL among the data lines DL. Although not illustrated, the first pads PD1 and the second pads PD2 may be electrically connected to each other. The second pads PD2 may be electrically connected to the third pads PD3 through connection signal lines SCLn.

The circuit board PB may include multiple board bump electrodes PB-BP. The board bump electrodes PB-BP may be arranged in the second direction DR2. The board bump electrodes PB-BP of the circuit board PB may be in contact with and electrically connected to the third pads PD3 of the second pad area PA2.

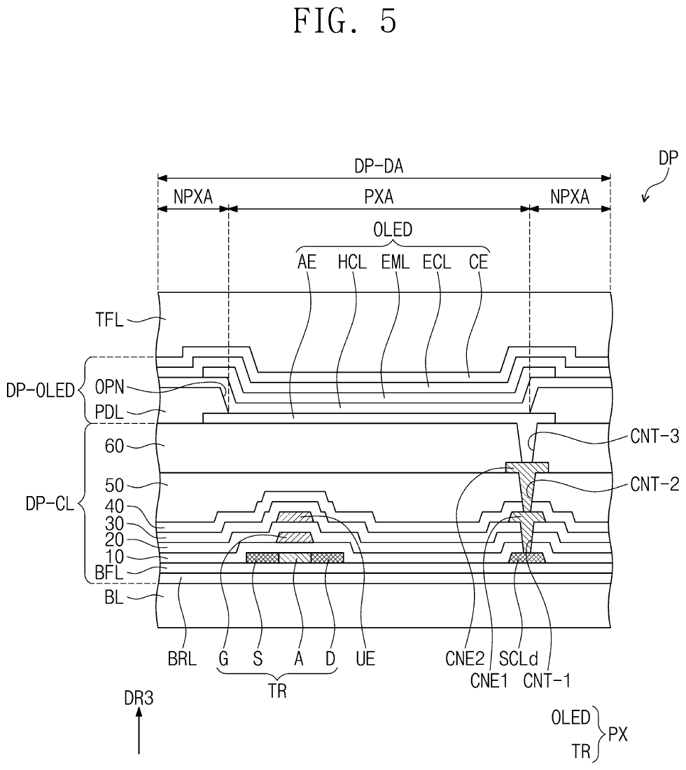

FIG. 5 is a schematic cross-sectional view of the display panel DP, which illustrates the pixel PX, according to an embodiment of the disclosure.

Referring to FIG. 5, the display area DP-DA may include a light emitting area PXA and a non-light emitting area NPXA disposed adjacent to the light emitting area PXA. Each of the pixels PX may include a light emitting element OLED and a pixel driving circuit electrically connected thereto. The pixel PX may include a transistor TR and the light emitting element OLED.

Although one transistor TR is illustrated in FIG. 5, but the disclosure is not limited thereto. The pixel PX according to an embodiment may include seven transistors and at least one capacitor, and the seven transistors and the capacitor may be electrically connected to each other. However, the numbers of transistors and capacitors constituting the pixel PX are not limited thereto.

The display panel DP may include multiple insulating layers, multiple semiconductor patterns, multiple conductive patterns, multiple signal lines, and the like. The insulating layer, the semiconductor layer, and the conductive layer may be formed by a manner such as coating or deposition. Thereafter, the insulating layer, the semiconductor layer, and the conductive layer may be selectively patterned by photolithography. For example, the semiconductor pattern, the conductive pattern, the signal line, and the like included in the circuit element layer DP-CL and the display element layer DP-OLED may be formed.

The base layer BL may include a synthetic resin layer. The base layer BL may have a multi-layer structure. For example, the base layer BL may have a three-layer structure of a synthetic resin layer, an inorganic layer, and a synthetic resin layer. For example, the synthetic resin layer may be a polyimide-based resin layer, and a material thereof is not particularly limited thereto. The base layer BL may include a glass substrate, a metal substrate, an organic/inorganic composite material substrate, or the like.

The circuit element layer DP-CL may include a barrier layer BRL, a buffer layer BFL, first to sixth insulating layers 10, 20, 30, 40, 50, and 60, the transistor TR, a connection signal line SCLd, an upper electrode UE, a first connection electrode CNE1, and a second connection electrode CNE2.

At least one inorganic layer may be disposed on an upper surface of the base layer BL. The inorganic layer may be formed in multiple layers. The barrier layer BRL may be disposed on the base layer BL. The buffer layer BFL may be disposed on the barrier layer BRL. The barrier layer BRL and the buffer layer BFL may be inorganic layers.

A semiconductor pattern may be disposed on the buffer layer BFL. The semiconductor pattern may include polysilicon. However, the disclosure is not limited thereto, and the semiconductor pattern may include an amorphous silicon or a metal oxide.

FIG. 5 illustrates a portion of the semiconductor pattern, and the semiconductor pattern may be further disposed in another area of the pixel PX in a plan view. The semiconductor pattern may be disposed in a specific rule across pixels. The semiconductor pattern has different electrical properties depending on whether the semiconductor pattern is doped. The semiconductor pattern may include a first area and a second area. The first area may be doped with an N-type dopant or a P-type dopant. A P-type transistor includes a doped area doped with the P-type dopant.

The first area may have a conductivity that is greater than a conductivity of the second area and may substantially serve as an electrode or a signal line. The second area may be an area having a low doping concentration or an undoped area and may substantially correspond to an active area (or a channel) of the transistor. In other words, a portion of the semiconductor pattern may be an active area of the transistor, another portion of the semiconductor pattern may be a source area or a drain area of the transistor, and still another portion of the semiconductor pattern may be a connection electrode or a connection signal line.

As illustrated in FIG. 5, a source area S, an active area A, and a drain area D of the transistor TR may be formed from the semiconductor pattern.

FIG. 5 illustrates a portion of the connection signal line SCLd formed from the semiconductor pattern. The connection signal line SCLd may be electrically connected to a drain area of any one of the transistors in the pixel PX.

The first insulating layer 10 may be disposed on the buffer layer BFL. The first insulating layer 10 may cover the semiconductor pattern. The first insulating layer 10 may commonly overlap multiple pixels PX. A gate G may be disposed on the first insulating layer 10. The gate G may be a portion of a metal pattern. The gate G may overlap the active area A in the third direction DR3. In a process of doping the semiconductor pattern, the gate G may function as a mask.

The second insulating layer 20 that covers the gate G may be disposed on the first insulating layer 10. The second insulating layer 20 may commonly overlap the pixels PX. The upper electrode UE may be disposed on the second insulating layer 20. The upper electrode UE may overlap the gate G of the transistor TR. The upper electrode UE may be a portion of the metal pattern. A portion of the gate G and the upper electrode UE overlapping the same may form a capacitor.

The third insulating layer 30 that covers the upper electrode UE may be disposed on the second insulating layer 20. The first connection electrode CNE1 disposed on the third insulating layer 30 may be electrically connected to the connection signal line SCLd through a contact hole CNT-1 penetrating the first to third insulating layers 10, 20, and 30.

The fourth insulating layer 40 that covers the first connection electrode CNE1 may be disposed on the third insulating layer 30. The first to fourth insulating layers 10 to 40 may be inorganic layers and/or organic layers and may have a single-layer or multi-layer structure.

The first connection electrode CNE1 may be disposed on the fourth insulating layer 40 and covered by the fifth insulating layer 50. In other embodiments, in an embodiment, both a first connection electrode disposed on the third insulating layer 30 and covered by the fourth insulating layer 40 and a first connection electrode disposed on the fourth insulating layer 40 and covered by the fifth insulating layer 50 may be included.

The fifth insulating layer 50 may be disposed on the fourth insulating layer 40. The fifth insulating layer 50 may be an organic layer. The second connection electrode CNE2 may be disposed on the fifth insulating layer 50. The second connection electrode CNE2 may be electrically connected to the first connection electrode CNE1 through a contact hole CNT-2 penetrating the fourth insulating layer 40 and the fifth insulating layer 50.

The sixth insulating layer 60 that covers the second connection electrode CNE2 may be disposed on the fifth insulating layer 50. The sixth insulating layer 60 may be an organic layer. A first electrode AE may be disposed on the sixth insulating layer 60. The first electrode AE may be electrically connected to the second connection electrode CNE2 through a contact hole CNT-3 penetrating the sixth insulating layer 60.

The circuit element layer DP-CL may include multiple connection electrodes electrically connected to the transistors, and some of multiple connection electrodes may be arranged on different layers. Although not illustrated, the first connection electrode CNE1 may extend and be electrically connected to the transistor TR. Positions of multiple connection electrodes are not limited thereto.

The display element layer DP-OLED may include a pixel defining film PDL disposed on the sixth insulating layer 60 and the light emitting element OLED. A pixel opening OPN may be defined in the pixel defining film PDL. The pixel opening OPN of the pixel defining film PDL may expose at least a portion of the first electrode AE. The light emitting area PXA may overlap a partial area of the first electrode AE, which is exposed by the pixel opening OPN.

A hole control layer HCL may be commonly disposed in the light emitting area PXA and the non-light emitting area NPXA. The hole control layer HCL may be disposed on the first electrode AE and include a hole transport layer and/or a hole injection layer. A light emitting layer EML may be disposed on the hole control layer HCL. The light emitting layer EML may be disposed in an area corresponding to the pixel opening OPN. For example, the light emitting layer EML may be formed separately from each of the pixels PX. However, the disclosure is not limited thereto, and the light emitting layer EML may be also commonly formed in multiple pixels PX using an open mask.

An electron control layer ECL may be disposed on the light emitting layer EML. The electron control layer ECL may include an electron transport layer and/or an electron injection layer. The hole control layer HCL and the electron control layer ECL may be commonly formed in the pixels PX using an open mask. A second electrode CE may be disposed on the electron control layer ECL. The second electrode CE may have an integral shape and may be commonly disposed in the pixels PX. The upper insulating layer TFL may be disposed on the second electrode CE. The upper insulating layer TFL may include multiple thin films.

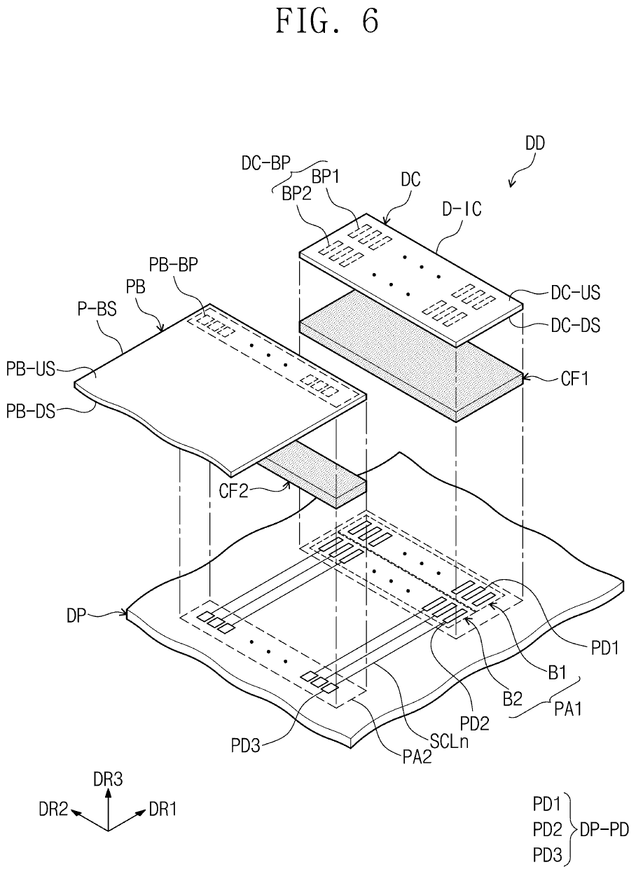

FIG. 6 is an enlarged schematic exploded perspective view of the pad areas PA1 and PA2 of the display device DD according to an embodiment of the disclosure. FIG. 6 illustrates the driving chip DC and the circuit board PB that are disassembled from the display panel DP. The first pads PD1, the second pads PD2, the connection signal lines SCLn, and the third pads PD3 of FIG. 6 are the same as the first pads PD1, the second pads PD2, the connection signal lines SCLn, and the third pads PD3 of FIG. 4, and thus descriptions thereof will be omitted or simplified.

Referring to FIGS. 4 and 6, the driving chip DC may be bonded to the first pad area PA1 through a first adhesive layer CF1. The circuit board PB may be bonded to the second pad area PA2 through a second adhesive layer CF2. The first and second adhesive layers CF1 and CF2 may include synthetic resins having adhesive properties. Each of the first and second adhesive layers CF1 and CF2 may be a non-conductive film. For example, the first and second adhesive layers CF1 and CF2 may not include conductive balls and may include only synthetic resins having adhesive properties.

The driving chip DC may include a driving integrated circuit D-IC and chip bump electrodes DC-BP mounted inside the driving chip DC. The driving integrated circuit D-IC may include an upper surface DC-US and a lower surface DC-DS, and the lower surface DC-DS may be a surface facing the first and second pads PD1 and PD2 in the third direction DR3. The chip bump electrodes DC-BP may be disposed on the lower surface DC-DS of the driving integrated circuit D-IC.

The chip bump electrodes DC-BP may include first bumps BP1 electrically connected to the first pads PD1 and second bumps BP2 electrically connected to the second pads PD2. The first bumps BP1 may be positioned in the second direction DR2, and the second bumps BP2 may be spaced apart from the first bumps BP1 in the first direction DR1 and positioned in the second direction DR2.

The driving chip DC may receive first signals through the second pads PD2 and the second bumps BP2 from an external unit. The driving chip DC may provide second signals generated based on the first signals to the first pads PD1 through the first bumps BP1. For example, the driving chip DC may include a data driving circuit. The first signal may be an image signal that is a digital signal applied from an external unit, and the second signal may be a data signal that is an analog signal. The driving chip DC may generate an analog voltage corresponding to a greyscale value of the image signal. The data signal may be provided to the pixels PX through the data line DL illustrated in FIG. 4.

Although not illustrated, the first bumps BP1 and the second bumps BP2 may have a shape that protrudes from the lower surface DC-DS of the driving integrated circuit D-IC in the third direction DR3 and is exposed to the outside. In case that the first adhesive layer CF1 is cured, the first pads PD1 and the first bumps BP1 may be fixed in a contact state, and the second pads PD2 and the second bumps BP2 may be fixed in a contact state.

The circuit board PB may include a base layer P-BS and the board bump electrodes PB-BP disposed on the circuit board PB. The circuit board PB may include an upper surface PB-US and a lower surface PB-DS, and the lower surface PB-DS may be a surface facing the third pads PD3 in the third direction DR3. The board bump electrodes PB-BP may be disposed on the lower surface PB-DS of the base layer P-BS. The board bump electrodes PB-BP may be electrically connected to the third pads PD3, respectively. The board bump electrodes PB-BP may be positioned in the second direction DR2. The circuit board PB may provide an image signal, a driving voltage, and other control signals to the driving chip DC.

Although not illustrated, the board bump electrodes PB-BP may have a shape that protrudes from the lower surface PB-DS of the base layer P-BS in the third direction DR3 and is exposed to the outside. In case that the second adhesive layer CF2 is cured, the third pads PD3 and the board bump electrodes PB-BP may be fixed in a contact state.

Electronic components may include a substrate and a bump electrode disposed under the substrate. In case that the electronic component corresponds to the driving chip DC, the substrate may correspond to the driving integrated circuit D-IC of the driving chip DC, and the bump electrode may correspond to the chip bump electrode DC-BP. In other embodiments, in case that the electronic component corresponds to the circuit board PB, the substrate may correspond to the base layer P-BS of the circuit board PB, and the bump electrode may correspond to the substrate bump electrode PB-BP.

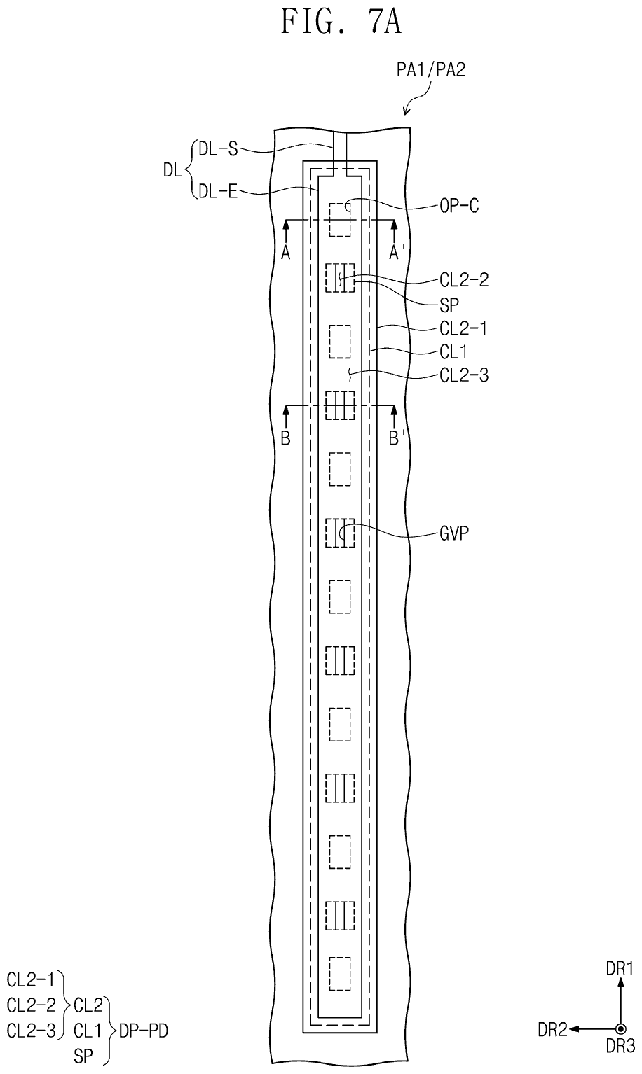

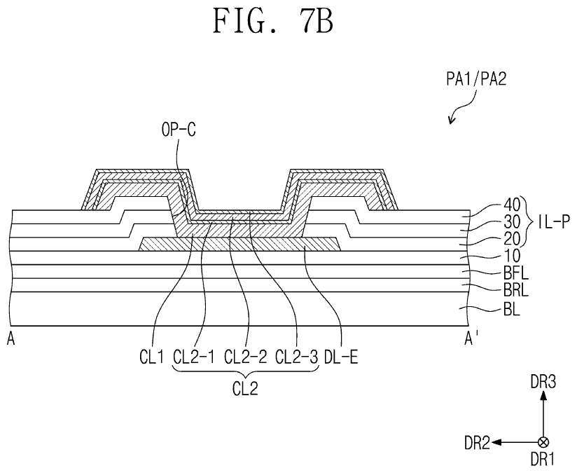

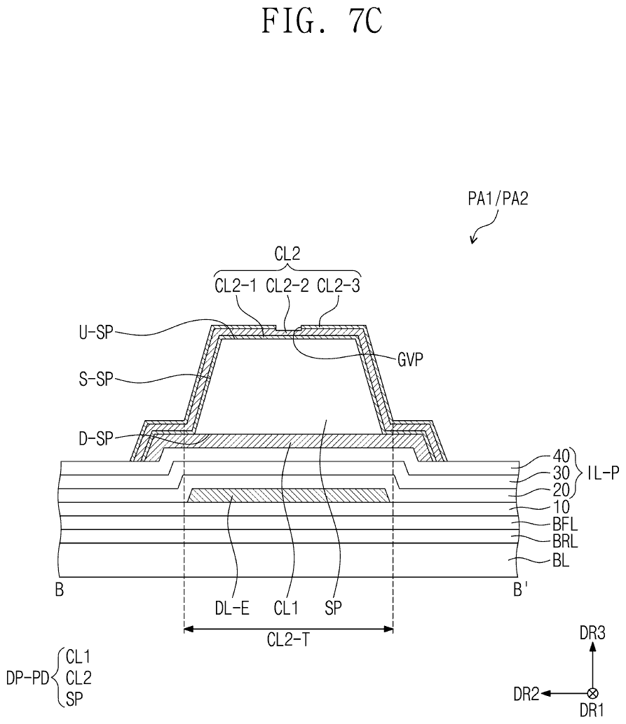

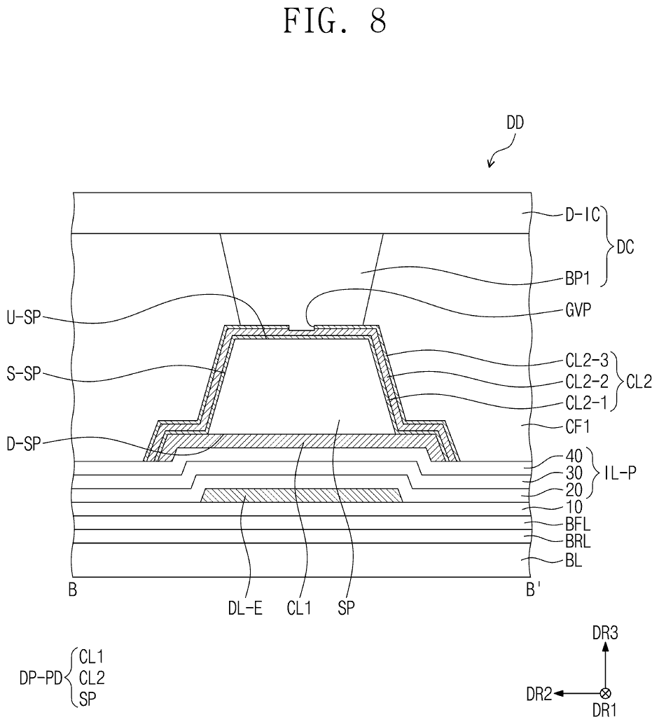

FIG. 7A is a schematic plan view of the pad areas PA1 and PA2 according to an embodiment of the disclosure. FIGS. 7B and 7C are schematic cross-sectional views of the pad areas PA1 and PA2 according to an embodiment of the disclosure. FIG. 7B is a schematic cross-sectional view of the pad areas PA1 and PA2 corresponding to line A-A′ in FIG. 7A, and FIG. 7C is a cross-sectional view of the pad areas PA1 and PA2 corresponding to line B-B′ in FIG. 7A. FIG. 8 is a schematic cross-sectional view illustrating a bonding structure of the display device DD according to an embodiment of the disclosure.

A signal pad DP-PD (or a signal pad structure) illustrated in FIGS. 7A to 8 may be any one of the first to third pads PD1 to PD3 described with reference to FIGS. 4 and 6. FIG. 7A illustrates a data line including an end portion DL-E and a line portion DL-S having different widths, but the disclosure is not limited thereto. Here, the width may mean a length or a width of the end portion DL-E or the line portion DL-S in the second direction DR2. The signal line may be a signal line other than the data line DL and may have a uniform width without distinction between the end portion DL-E and the line portion DL-S. The end portion DL-E may correspond to the pad part described above in FIG. 4.

Hereinafter, the pad areas PA1 and PA2 will be described while focusing on the first pad area PA1 in which the data line DL is disposed. The description of the first pad area PA1 may be equally applied to the second pad area PA2 except that the connection signal line SCLn (see FIG. 4) instead of the data line DL is disposed.

Referring to FIG. 7A, the signal pad DP-PD may include a first conductive pattern CL1, a second conductive pattern CL2, and at least one insulating pattern SP. The first conductive pattern CL1 may be electrically connected to the end portion DL-E of the data line DL through at least one contact hole OP-C. FIG. 7A illustrates the signal pad DP-PD including seven contact holes OP-C and six insulating patterns SP, and the numbers of contact holes OP-C positioned in the first direction DR1 and insulating patterns SP positioned in the first direction DR1 are not limited thereto.

In a plan view, the end portion DL-E may have a shape extending in the first direction DR1. For example, a length or a width of the end portion DL-E in the first direction DR1 may be greater than a length or a width thereof in the second direction DR2.

In a plan view, the contact holes OP-C may overlap the end portion DL-E. The contact holes OP-C may be arranged in the first direction DR1. The contact holes OP-C may be spaced apart from each other in the first direction DR1. In a plan view, a portion of the first conductive pattern CL1 may overlap the contact holes OP-C.

In a plan view, the insulating patterns SP may overlap the second conductive pattern CL2. In a plan view, the insulating patterns SP may be spaced apart from the contact holes OP-C. The insulating patterns SP may be arranged in the first direction DR1. The insulating patterns SP may be spaced apart from each other in the first direction DR1.

The insulating patterns SP may be arranged between the adjacent contact holes OP-C in the first direction DR1. FIG. 7A illustrates each of six insulating patterns SP may be arranged in each of seven contact holes OP-C, but an arrangement relationship therebetween is not limited thereto.

FIG. 7A illustrates the insulating patterns SP having a square in a plan view, but the disclosure is not limited thereto. The shape of the insulating patterns SP in a plan view may be changed to a polygonal shape, a circular shape, an elliptic shape other than the square. The shapes of the insulating patterns SP are not limited thereto.

Referring to FIGS. 7B and 7C, the end portion DL-E may be disposed on the first insulating layer 10. The end portion DL-E may be disposed on the same layer as the gate G illustrated in FIG. 5. The end portion DL-E may be formed through the same process as the gate G. The end portion DL-E may include the same material as the gate G.

However, a position of the end portion DL-E is not limited thereto. The end portion DL-E may be disposed on the same layer as the upper electrode UE illustrated in FIG. 5, may include the same material as the upper electrode UE, and may have the same laminate structure as the upper electrode UE. In other embodiments, some of multiple signal lines may be formed through the same process as the gate G (see FIG. 5), and the others thereof may be formed through the same process as the upper electrode UE (see FIG. 5).

The data line DL may be disposed on one layer and have an integrated shape, but the disclosure is not limited thereto. The one data line DL may include multiple portions arranged on different layers. For example, the line portion DL-S (see FIG. 7A) may include two or more portions.

The first conductive pattern CL1 may be disposed on the fourth insulating layer 40. The first conductive pattern CL1 may be electrically connected to the end portion DL-E through the contact hole OP-C penetrating the second to fourth insulating layers 20, 30, and 40. For example, the first conductive pattern CL1 may be in contact with the end portion DL-E through the contact hole OP-C. The second to fourth insulating layers 20, 30, and 40 may be formed through the same process as the second to fourth insulating layers 20, 30, and 40 of the display area DP-DA illustrated in FIG. 5. The insulating layers arranged between the end portion DL-E and the first conductive pattern CL1 may be defined as pad insulating layers IL-P. The second to fourth insulating layers 20, 30, and 40 may be defined as the pad insulating layers IL-P. A laminated structure of the pad insulating layers IL-P may be changed depending on a laminated structure of the circuit element layer DP-CL (see FIG. 5). The contact hole OP-C may be defined by a larger number of insulating layers than the second to fourth insulating layers 20, 30, and 40 or may be defined by a smaller number of insulating layers than the second to fourth insulating layers 20, 30, and 40.

The first conductive pattern CL1 and the end portion DL-E may be distinguished from each other by the pad insulating layers IL-P (e.g., the second to fourth insulating layers 20, 30, and 40) arranged therebetween.

The second conductive pattern CL2 may be disposed on the first conductive pattern CL1. An area of the second conductive pattern CL2, which does not overlap the insulating pattern SP, may be in contact with the first conductive pattern CL1.

The first conductive pattern CL1 may be formed through the same process as the first connection electrode CNE1 described above in FIG. 5, and the second conductive pattern CL2 may be formed through the same process as the second connection electrode CNE2 described above in FIG. 5. The first conductive pattern CL1 may include the same material as the first connection electrode CNE1 (see FIG. 5), and the second conductive pattern CL2 may include the same material as the second connection electrode CNE2 (see FIG. 5). FIGS. 7B and 7C illustrate an embodiment in which the first conductive pattern CL1 is disposed on the fourth insulating layer 40. The first conductive pattern CL1 may be disposed on the third insulating layer 30, and for example, the fourth insulating layer 40 may not be disposed in the pad areas PA1 and PA2. However, the disclosure is not limited thereto, and a combination of the connection electrodes formed through the same process as the first and second conductive patterns CL1 and CL2 may be variously selected according to the laminated structure of the circuit element layer DP-CL (see FIG. 5) as long as the first and second conductive patterns CL1 and CL2 having different layers are provided.

In a plan view, it is illustrated that the second conductive pattern CL2 has a larger area than the first conductive pattern CL1, an edge of the second conductive pattern CL2 is disposed on an outer side of an edge of the first conductive pattern CL1, and the second conductive pattern CL2 covers the edge of the first conductive pattern CL1, but the disclosure is not limited thereto. The second conductive pattern CL2 may have substantially the same area as the first conductive pattern CL1, and the edge of the second conductive pattern CL2 may be substantially aligned with the edge of the first conductive pattern CL1.

A portion of the second conductive pattern CL2 may include a portion that overlaps the insulating pattern SP in a plan view. The insulating pattern SP may be disposed between the first conductive pattern CL1 and the second conductive pattern CL2 on a cross section. The insulating pattern SP may be disposed on the first conductive pattern CL1 and may be covered by the second conductive pattern CL2. The second conductive pattern CL2 may cover an upper surface U-SP and a side surface S-SP of the insulating pattern SP.

A lower surface D-SP of the insulating pattern SP may be defined as a surface on which the insulating pattern SP is in contact with the first conductive pattern CL1. The upper surface U-SP of the insulating pattern SP may be defined as a surface opposite to the lower surface D-SP among surfaces on which the insulating pattern SP is in contact with the second conductive pattern CL2. The side surface S-SP of the insulating pattern SP may be defined as a surface except for the upper surface U-SP among surfaces on which the insulating pattern SP is in contact with the second conductive pattern CL2.

The insulating pattern SP may have a trapezoidal shape in a cross-sectional view. The insulating pattern SP may have the inclined side surface S-SP, and an inclination of the side surface S-SP with respect to the lower surface D-SP may be an acute angle. However, the present disclosure is not limited thereto, and the insulating pattern SP may have a rectangular shape or have an inverted trapezoidal shape in a cross-sectional view.

The insulating pattern SP may include a polymer. The insulating pattern SP may include a thermosetting polymer. However, the present disclosure is not limited thereto, and the insulating pattern SP may include a thermoplastic polymer.

The insulating pattern SP may be formed through the same process as the fifth insulating layer 50 (see FIG. 5). Accordingly, an additional process for forming the insulating pattern SP may not be required. However, the disclosure is not limited thereto, and a combination of the connection electrodes formed through the same process as the first and second conductive patterns CL1 and CL2 may be variously selected according to the laminated structure of the circuit element layer DP-CL (see FIG. 5). Accordingly, the insulating layer formed through the same process as the insulating pattern SP may be also variously selected.

A portion of the second conductive pattern CL2, which covers the insulating pattern SP, may protrude from the first conductive pattern CL1 in the third direction DR3 as compared to the other portions of the second conductive pattern CL2. A protruding portion of the second conductive pattern CL2 may be referred to as a protruding portion CL2-T. The second conductive pattern CL2 may be in contact with an upper surface of the first conductive pattern CL1, which does not overlap the insulating pattern SP, the side surface S-SP of the insulating pattern SP, and the upper surface U-SP of the insulating pattern SP. The protruding portion CL2-T of the second conductive pattern CL2 may correspond to a portion in contact with the side surface S-SP of the insulating pattern SP and the upper surface U-SP of the insulating pattern SP.

The second conductive pattern CL2 may include a first layer CL2-1, a second layer CL2-2, and a third layer CL2-3 that are sequentially laminated. The first layer CL2-1 may be disposed on the first conductive pattern CL1. The first layer CL2-1 may be in contact with the upper surface of the first conductive pattern CL1, which does not overlap the insulating pattern SP, the side surface S-SP of the insulating pattern SP, and the upper surface U-SP of the insulating pattern SP. The second layer CL2-2 may be disposed on the first layer CL2-1. The first layer CL2-1 may cap a lower surface of the second layer CL2-2. The third layer CL2-3 may be disposed on the second layer CL2-2. The third layer CL2-3 may cap an upper surface of the second layer CL2-2.

A thickness of the second layer CL2-2 in the third direction DR3 (e.g., thickness direction) may be greater than a thickness of the first layer CL2-1 in the third direction DR3 (e.g., thickness direction). A thickness of the third layer CL2-3 in the third direction DR3 (e.g., thickness direction) may be smaller than the thickness of the second layer CL2-2 in the third direction DR3 (e.g., thickness direction). The second layer CL2-2 may have higher conductivity than those of the first layer CL2-1 and the third layer CL2-3. The second layer CL2-2 may include a material having higher conductivity than that of a material included in the first layer CL2-1 and the third layer CL2-3. The first layer CL2-1 and the third layer CL2-3 may include the same material. The second layer CL2-2 may include a material different from the material included in the first layer CL2-1 and the third layer CL2-3. For example, the first layer CL2-1 and the third layer CL2-3 may include titanium (Ti), and the second layer CL2-2 may include aluminum (Al).

The second conductive pattern CL2 may further include an oxide film (not illustrated) disposed on an upper surface of the third layer CL2-3 and covering the third layer CL2-3. For example, the oxide film disposed on the upper surface of the third layer CL2-3 may include titanium oxide (TiOₓ).

As the second layer CL2-2 is covered by the third layer CL2-3, in case that the second layer CL2-2 is in contact with the first adhesive layer CF1, a surface of the second layer CL2-2 may be prevented from being oxidized. Oxidation of the second layer CL2-2 by oxygen atoms (O) that may be included in the first adhesive layer CF1 may be prevented.

A groove pattern GVP may be defined in the second conductive pattern CL2.

Referring to FIG. 7A, the groove pattern GVP may be disposed on an area of the second conductive pattern CL2, which overlaps the insulating pattern SP. FIG. 7A illustrates that a shape of the groove pattern GVP in a plan view is a rectangular shape elongated in the first direction DR1, but this is an example, and the shape of the groove pattern GVP in a plan view may be a polygonal shape, a circular shape, an elliptic shape or the like other than the rectangular shape. It is illustrated that the groove pattern GVP including one groove is disposed to overlap the one insulating pattern SP, but this is an example, and the groove pattern GVP including two or more grooves may overlap the one insulating pattern SP.

The groove pattern GVP may be a single groove or multiple grooves or a single crack or multiple cracks on a cross section and is not limited as long as the groove pattern GVP is disposed on the upper surface U-SP of the insulating pattern SP and has a shape that exposes the second layer CL2-2.

Referring to FIG. 7C, the groove pattern GVP may penetrate the third layer CL2-3 and expose the second layer CL2-2. The groove pattern GVP may be defined by the protruding portion CL2-T of the second conductive pattern CL2, which is disposed on and protrudes from the insulating pattern SP.

As illustrated in FIG. 7C, the groove pattern GVP may be defined by the third layer CL2-3 of the second conductive pattern CL2, which is disposed on the upper surface U-SP of the insulating pattern SP. For example, the groove pattern GVP may be an opening pattern that penetrates the third layer CL2-3. The opening pattern may penetrate the third layer CL2-3 and expose the upper surface of the second layer CL2-2.

In other embodiments, although not illustrated, the groove pattern GVP may be defined by a portion of the second layer CL2-2 and the third layer CL2-3 of the second conductive pattern CL2, which are arranged on the upper surface U-SP of the insulating pattern SP. For example, the groove pattern GVP may include the opening pattern that penetrates the third layer CL2-3 and a groove pattern extending from the opening pattern and defined on the upper surface of the second layer CL2-2.

FIG. 8 schematically illustrates the driving chip DC as an electronic component. FIG. 8 illustrates a state in which the first bump BP1 among the chip bump electrodes DC-BP (see FIG. 6) of the driving chip DC is in contact with the first pad PD1 (see FIG. 6). In FIG. 8, the first pad PD1 (see FIG. 6) is illustrated as the signal pad DP-PD.

Through a bonding process, the first bump BP1 of the driving chip DC may penetrate the first adhesive layer CF1 and come into contact with the second conductive pattern CL2 of the signal pad DP-PD.

In the case of the display device DD of the disclosure, a shape of a boundary surface in which the first bump BP1 and the second layer CL2-2 are in contact with each other may be a single groove shape, multiple groove shapes spaced apart from each other at regular intervals, or multiple crack shapes. In the case of multiple groove shapes or multiple crack shapes, depths of the groove shapes and the crack shapes may be substantially the same. For example, unlike the disclosure, the signal pad in which the groove pattern GVP is not defined has crack shapes having various intervals and/or depths that is caused by tearing the second layer due to pressing during bonding.

The display device DD of the disclosure may be electrified through direct contact between the bump BP1 and the second layer CL2-2 of the second conductive pattern CL2. In detail, reliability of the electrical connection may be further improved by forming a physical and chemical bonding between a material constituting the bump BP1 and a material constituting the second layer CL2-2.

For example, the display device DD of the disclosure does not include a conductive ball, and thus even in case that the signal pads DP-PD are crowded, a short circuit caused by the conductive ball and/or an electrification failure in case that the conductive ball is not disposed between the signal pad DP-PD and the bump electrode may be prevented. Accordingly, it may be advantageous to implement a high-resolution panel.

In the display device DD of the disclosure, the groove pattern GVP is defined on an upper surface of the second conductive pattern CL2, and thus bonding reliability between the signal pad DP-PD and an electronic component such as the driving chip DC (see FIG. 6) or the circuit board PB (see FIG. 6) may be improved.

As compared to a case in which there is no groove pattern GVP in the second conductive pattern CL2, an area in which the bump electrodes DC-BP and PB-BP (see FIG. 6) of the electronic component and the second layer CL2-2 exposed by the groove pattern GVP are in direct contact with each other may be increased. An area in which the bump electrodes DC-BP and PB-BP (see FIG. 6) and the second layer CL2-2 are in direct contact with each other is sufficiently provided, and thus, initial resistance and reliability resistance may be improved.

Because the groove pattern GVP is formed in the second conductive pattern CL2 in advance immediately before the bonding, the bonding process may be performed at a low pressure as compared to a case in which there is no groove pattern GVP. In case that the groove pattern GVP is not present in the second conductive pattern CL2, cracks are formed in the third layer CL2-3 by the pressing during the bonding, and thus the second layer CL2-2 should be exposed and the second layer CL2-2 should be brought into contact with the bump electrode. For example, a high pressure process is required. In the disclosure, a low pressure process is possible, and thus, defects that occur in case that a film included in the display panel DP (see FIG. 6) is lifted during the bonding may be also prevented. Because the bonding process is performed immediately after the groove pattern GVP is formed, oxidation of the exposed second layer CL2-2 may be prevented.

Hereinafter, a method of manufacturing the display device according to an embodiment will be described with reference to the drawings. In the description of the method of manufacturing the display device of an embodiment, a description of a content that is duplicated with the above-described content of the display device according to an embodiment will be omitted.

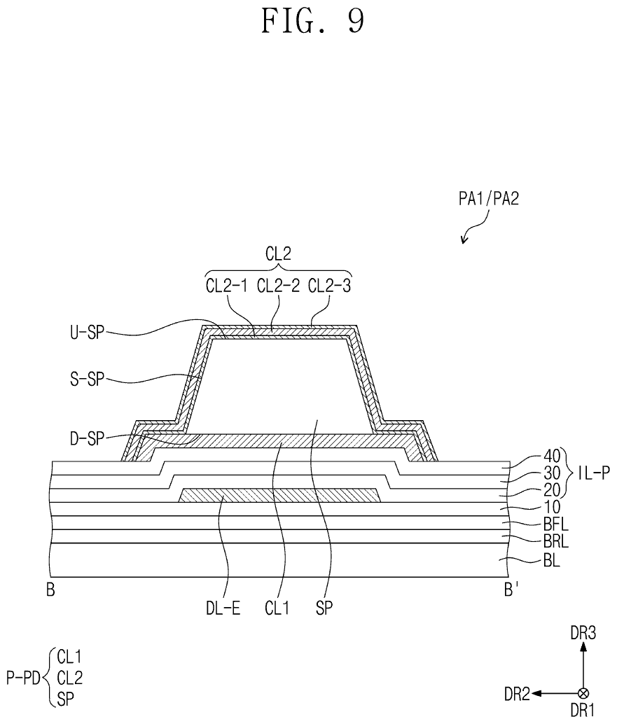

FIGS. 9 to 11D are schematic cross-sectional views illustrating one operation of a method of manufacturing the display device according to an embodiment of the disclosure.

For convenience of description, FIGS. 9 to 11D illustrate cross sections of portions corresponding to line B-B′ of FIG. 7A. In FIGS. 9 to 11D, the description of FIGS. 4 to 7C may be equally applied to the same configuration, and a detailed description thereof will be omitted.

The method of manufacturing the display device according to an embodiment may include an operation of providing a preliminary signal pad P-PD and an operation of manufacturing the signal pad DP-PD by forming the groove pattern GVP.

FIG. 9 is a schematic cross-sectional view illustrating the operation of providing the preliminary signal pad P-PD. Referring to FIG. 9, the preliminary signal pad P-PD may include the first conductive pattern CL1, the second conductive pattern CL2, and the insulating pattern SP.

The first conductive pattern CL1 may be disposed on the base layer BL. The first conductive pattern CL1 may be electrically connected to a signal line (e.g., the data line DL) (see FIG. 4). The second conductive pattern CL2 may be disposed on the first conductive pattern CL1. The insulating pattern SP may be disposed between the first conductive pattern CL1 and the second conductive pattern CL2.

The second conductive pattern CL2 may include the first layer CL2-1, the second layer CL2-2, and the third layer CL2-3 that are sequentially laminated. For example, the second layer CL2-2 may be disposed between the first layer CL2-1 and the third layer CL2-3. The first layer CL2-1 may cover the insulating pattern SP and a portion of the first conductive pattern CL1 in which the insulating pattern SP is not disposed. The second layer CL2-2 may cover the first layer CL2-1. The third layer CL2-3 may cover the second layer CL2-2.

Each of the thickness of the first layer CL2-1 and the thickness of the third layer CL2-3 may be smaller than the thickness of the second layer CL2-2.

The first layer CL2-1 and the third layer CL2-3 may include a different material from that of the second layer CL2-2. A material included in the second layer CL2-2 may have greater conductivity than that of a material included in the first layer CL2-1 and the third layer CL2-3. For example, the first layer CL2-1 and the third layer CL2-3 may include titanium (Ti), and the second layer CL2-2 may include aluminum (Al). The upper surface of the third layer CL2-3 may further include an oxide film (not illustrated). For example, the oxide film may include a titanium oxide (TiOₓ). The second layer CL2-2 may be covered by the third layer CL2-3, and thus oxidation thereof may be prevented.

The first and second conductive patterns CL1 and CL2 may be formed through a process such as coating and deposition. The first and second conductive patterns CL1 and CL2 may be selectively patterned through a photolithography and an etching process.

The insulating pattern SP may have a trapezoidal shape in a cross-sectional view. However, the disclosure is not limited thereto, and the insulating pattern SP may have a rectangular shape in a cross-sectional view or have an inverted trapezoidal shape.

The insulating pattern SP may include a polymer. The insulating pattern SP may include a thermosetting polymer. However, the disclosure is not limited thereto, and the insulating pattern SP may include a thermoplastic polymer.

The content described above in FIG. 7A may be applied to the arrangement of the first and second conductive patterns CL1 and CL2 and the insulating pattern SP in a plan view.

The barrier layer BRL, the buffer layer BFL, the end portion DL-E of the signal line (e.g., the data line DL) (see FIG. 4), and the pad insulating layer IL-P may be further disposed between the base layer BL and the preliminary signal pad P-PD.

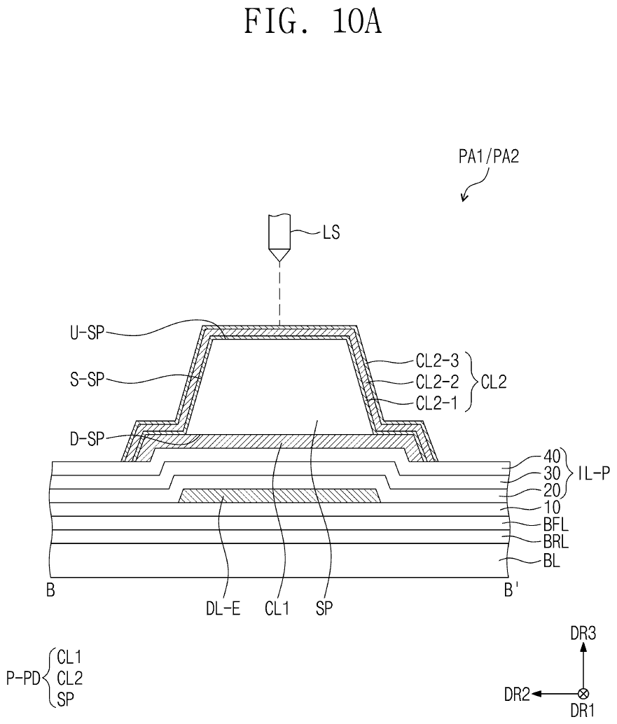

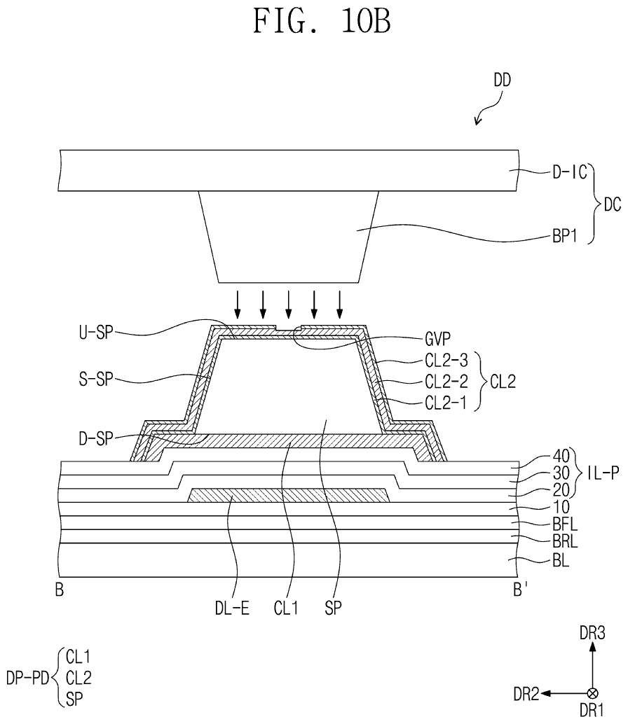

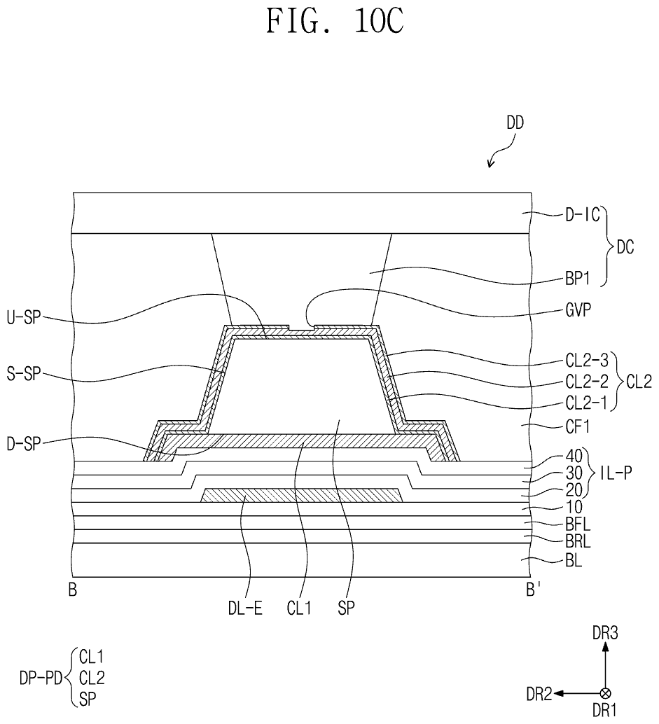

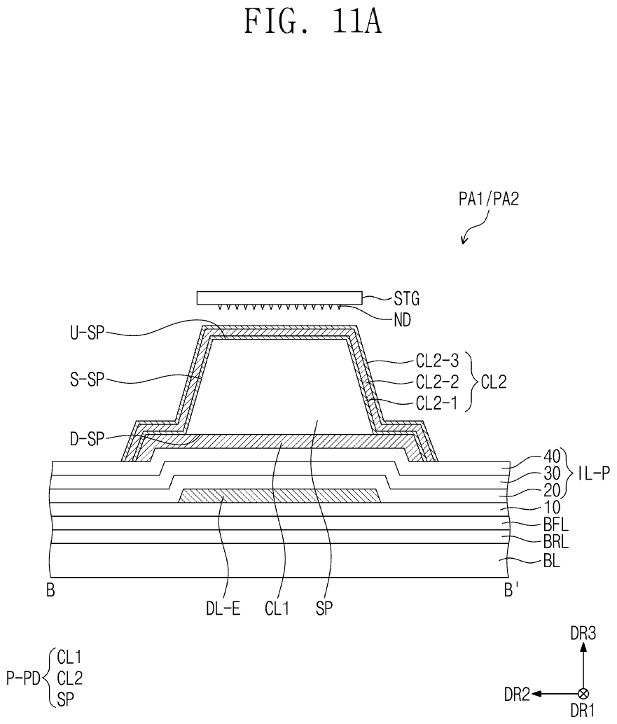

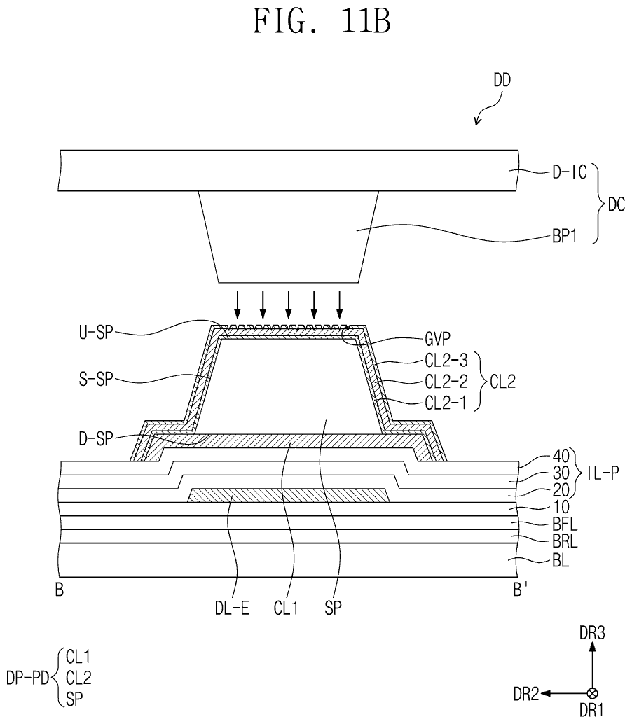

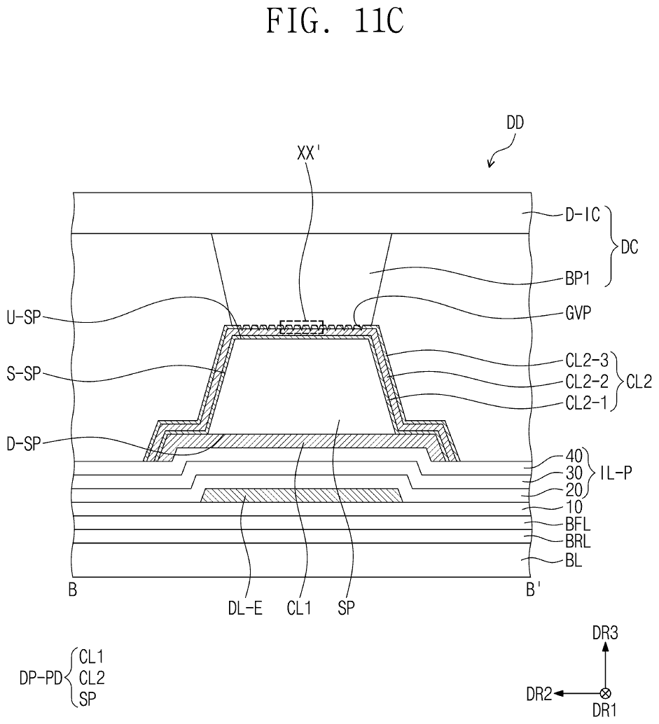

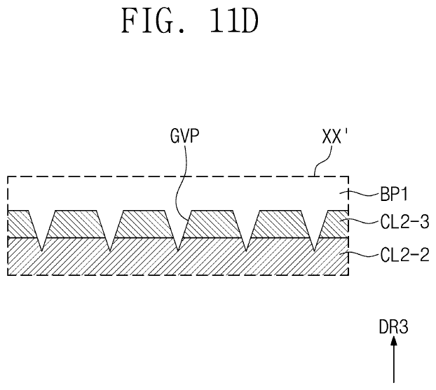

FIGS. 10A and 11A are schematic cross-sectional views illustrating the operation of manufacturing the signal pad DP-PD by forming the groove pattern GVP. In FIGS. 10B and 11B, the groove pattern GVP may be formed in the second conductive pattern CL2 immediately before the bonding process which will be described below. Because the groove pattern GVP is formed immediately before the bonding process, oxidation of the exposed second layer CL2-2 may be prevented in case that the signal pad DP-PD is stored for an intermediate process in contrast.

FIGS. 10A and 11A illustrate a process of forming the groove pattern GVP.

Referring to FIG. 10A, the process of forming the groove pattern GVP in the second conductive pattern CL2 may be a laser LS process. A process of etching an upper portion of the second conductive pattern CL2 using the laser LS is schematically illustrated.

The third layer CL2-3 of the second conductive pattern CL2 may be etched using the laser LS so that the second layer CL2-2 may be exposed. In other embodiments, portions of the third layer CL2-3 and the second layer CL2-2 of the second conductive pattern CL2 may be etched so that the second layer CL2-2 may be exposed.

Thereafter, in the bonding process, the groove pattern GVP may be formed in an area that overlaps the upper surface U-SP of the insulating pattern SP in a plan view so that the second layer CL2-2 exposed by the groove pattern GVP is in contact with the bump BP1. For example, the groove pattern GVP may be defined at a portion of the second conductive pattern CL2, which covers the upper surface U-SP of the insulating pattern SP. The groove pattern GVP may include multiple grooves.

FIG. 10A illustrates that one groove is patterned on the one insulating pattern SP by laser LS patterning in the first direction DRI as described above in FIG. 7A. However, the disclosure is not limited thereto, the laser LS patterning may be also performed in the second direction DR2, and the number of grooves may be two or more on the one insulating pattern SP. In other embodiments, the patterning may be performed in a direction other than the first and second directions DR1 and DR2, and the patterning may be performed in a point shape rather than a line shape or other polygonal shapes or a circular shape.

Referring to FIG. 11A, the process of forming the groove pattern GVP in the second conductive pattern CL2 may be a fine needle ND process. A process of forming a crack in an upper portion of the second conductive pattern CL2 using the fine needle ND is schematically illustrated. The fine needle ND may be disposed on a lower surface of a stage STG. The groove pattern GVP may be defined as a crack shape.

The fine needle ND may be applied as long as the fine needle ND is made of a material having a hardness that is greater than that of a layer of the second conductive pattern CL2, which is to be etched. For example, in case that the third layer CL2-3 of the second conductive pattern CL2 is titanium (Ti), the fine needle ND may include a material having a hardness that is greater than that of titanium. In case that a portion of the second layer CL2-2 is also to be etched, for example, the second layer CL2-2 may be aluminum (Al), and the fine needle ND may include a material having a hardness that is greater than those of titanium and aluminum. For example, the fine needle ND may include quartz or SUS.

The third layer CL2-3 of the second conductive pattern CL2 may be etched using the fine needle ND so that the second layer CL2-2 may be exposed. In other embodiments, the portions of the third layer CL2-3 and the second layer CL2-2 of the second conductive pattern CL2 may be etched so that the second layer CL2-2 may be exposed.

Thereafter, in the bonding process, the groove pattern GVP may be formed in an area that overlaps the upper surface U-SP of the insulating pattern SP in a plan view so that the second layer CL2-2 exposed by the groove pattern GVP is in contact with the bump BP1. For example, the groove pattern GVP may be defined at the portion of the second conductive pattern CL2, which covers the upper surface U-SP of the insulating pattern SP. The groove pattern GVP may include multiple cracks. Multiple cracks may be formed in a shape corresponding to the fine needle ND.

FIG. 11A illustrates that the patterning is performed while moving the fine needle ND in the first direction DR1, but the disclosure is not limited thereto, and the patterning may be performed while moving the fine needle ND in the second direction DR2 or the patterning may be performed while moving the fine needle ND in other directions. In other embodiments, the patterning may be performed in a point shape rather than a line shape or other polygonal shapes or a circular shape. The number of fine needles ND may be one or two or more.

The method of manufacturing the display device according to an embodiment may further include an operation of bonding the signal pad DP-PD and an electronic component (e.g., the driving chip DC).

FIGS. 10B and 11B are schematic cross-sectional views illustrating the operation of bonding the signal pad DP-PD including the groove pattern GVP and the driving chip DC. The driving chip DC of FIGS. 10B and 11B is illustrative and may also be applied to other electronic components such as the circuit board PB (see FIG. 6).

The operation of bonding the signal pad DP-PD and the driving chip DC may be performed immediately after the groove pattern GVP is formed in FIGS. 10A and 11A. Thus, the oxidation of the second layer CL2-2 exposed by the groove pattern GVP may be prevented.

FIG. 10B illustrates a bonding process after forming the groove pattern GVP using the laser LS process of FIG. 10A, and FIG. 11B illustrates a bonding process after forming the groove pattern GVP using the fine needle ND process of FIG. 11A.

Because the groove pattern GVP is formed in the second conductive pattern CL2 in advance immediately before the bonding, the bonding process may be performed at a low pressure as compared to a case in which there is no groove pattern GVP. In case that the groove pattern GVP is not present in the second conductive pattern CL2, cracks are formed in the third layer CL2-3 by the pressing during the bonding, and thus the second layer CL2-2 should be exposed and the second layer CL2-2 should be brought into contact with the bump electrode. Accordingly, high-pressure pressing is required.

In the bonding process of the disclosure, a low pressure process is possible, and thus, defects that occur in case that a film included in the display panel DP (see FIG. 6) is lifted during the bonding may be also prevented.

FIGS. 10C and 11C schematically illustrate the display device DD in a state in which the pad area is bonded. FIG. 10C illustrates the display device DD after the bonding process of FIG. 10B, and FIG. 11C illustrates the display device DD after the bonding process of FIG. 11B.

FIG. 11D is an enlarged schematic view illustrating a portion XX' of a contact portion between the bump BP1 and the second conductive pattern CL2 of FIG. 11C. The bump BP1 may penetrate the third layer CL2-3 due to the groove pattern GVP in the third direction DR3 and may be in direct contact with the second layer CL2-2. The display device DD may be electrified by the physical and chemical bonding between the material constituting the bump BP1 and the material constituting the second layer CL2-2. A contact portion between the bump BP1 and the second conductive pattern CL2 of FIG. 10C is merely different in a contact shape due to the different shape of the groove pattern GVP, and the bump BP1 is the same as that illustrated in FIG. 11D in that the bump BP1 penetrates the third layer CL2-3 by the groove pattern GVP and is in direct contact with the second layer CL2-2.

The same content described above in FIG. 8 may be equally applied to the display device DD in a state in which the pad area is bonded, and thus a detailed description thereof will be omitted.

The display device DD manufactured according to the manufacturing method of the disclosure may be electrified through the direct contact between the bump BP1 and the second layer CL2-2 of the second conductive pattern CL2. The reliability of the electrical connection may be further improved by forming the physical and chemical bonding between the material constituting the bump BP1 and the material constituting the second layer CL2-2.

For example, the display device DD manufactured according to the manufacturing method of the disclosure does not include a conductive ball, and thus even in case that the signal pads DP-PD are crowded, a short circuit caused by the conductive ball and/or an electrification failure in case that the conductive ball is not disposed between the signal pad DP-PD and the bump electrode may be prevented. Accordingly, it may be advantageous to implement a high-resolution panel.

The manufacturing method of the disclosure includes an operation of forming the groove pattern GVP on the second conductive pattern CL2, and thus the bonding reliability between the signal pad DP-PD and the electronic component such as the driving chip DC or the circuit board PB (see FIG. 6) may be improved.

In detail, as compared to a case in which the bonding process is performed while the groove pattern GVP is not formed in the second conductive pattern CL2, an area in which the bump electrodes DC-BP and PB-BP (see FIG. 6) of the electronic component and the second layer CL2-2 exposed by the groove pattern GVP are in direct contact with each other may be increased. An area in which the bump electrodes DC-BP and PB-BP (see FIG. 6) and the second layer CL2-2 are in direct contact with each other is sufficiently provided, and thus, initial resistance and reliability resistance may be improved.

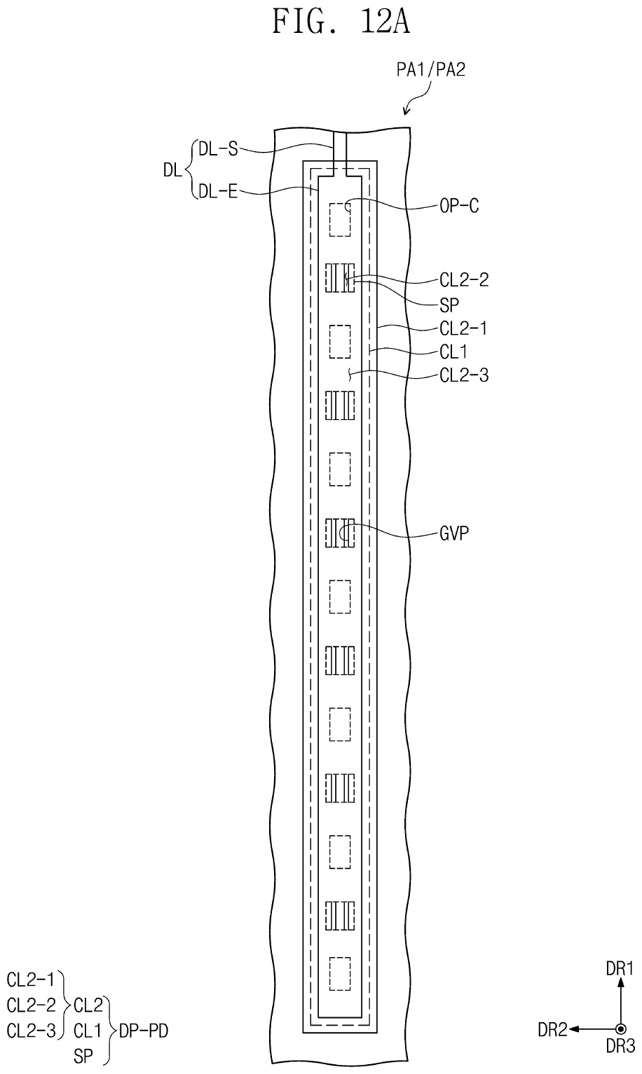

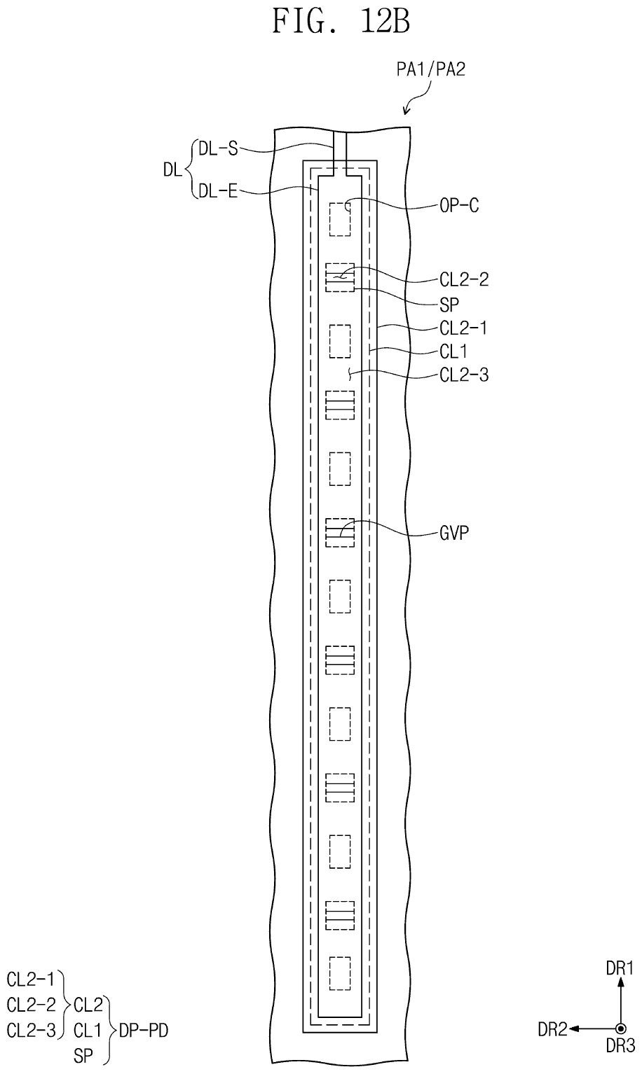

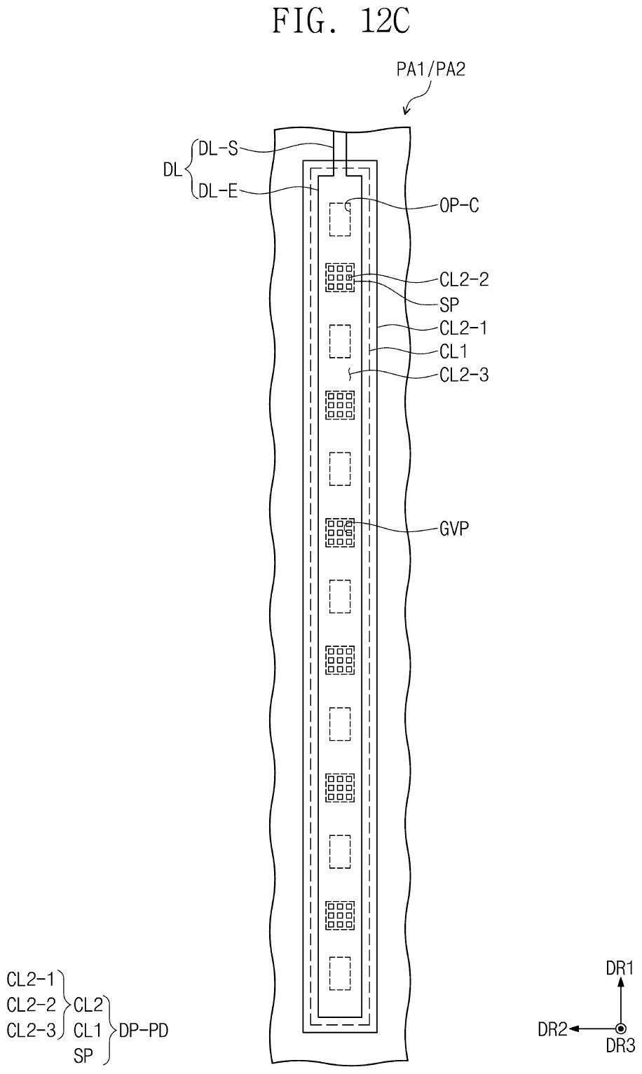

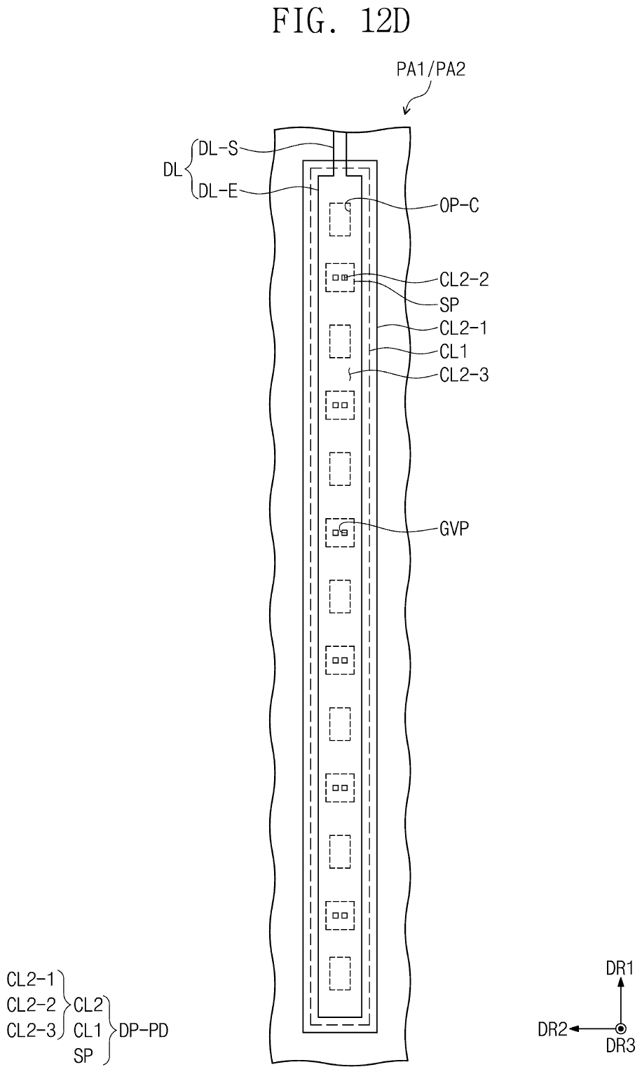

FIGS. 12A to 12D are schematic plan views of a pad area according to an embodiment of the disclosure.

A length in the first direction DR1, a length in the second direction DR2 and/or an area of the grooves included in the groove pattern GVP of FIGS. 12A to 12D are schematically and illustrated for description, and the disclosure is not limited to the length and/or the area illustrated in the drawings.

FIG. 12A illustrates that the pad areas PA1 and PA2 include a line or rectangular groove pattern GVP extending in the first direction as in FIG. 7A but the groove pattern GVP including two grooves is defined on the one insulating pattern SP.

FIG. 12B illustrates that the pad areas PA1 and PA2 include the groove pattern GVP including one groove on the one insulating pattern SP as in FIG. 7A, but the groove pattern GVP has a line or rectangular shape extending in the second direction DR2.

FIG. 12C illustrates that the pad areas PA1 and PA2 include the groove pattern GVP including nine grooves having a point or square shape on the one insulating pattern SP. The number and sizes/areas/positions of the grooves having the point or square shape are not limited thereto and may be variously applied.

FIG. 12D illustrates that the pad areas PA1 and PA2 include the groove pattern GVP including two grooves having a square shape on the one insulating pattern SP. The number and sizes/areas/positions of the grooves having the square shape are not limited thereto and may be variously applied.

The groove pattern GVP of FIGS. 12A to 12D may be patterned using the laser LS (see FIG. 10A) or may be patterned using the fine needle ND (see FIG. 11A). However, the method of patterning the groove pattern GVP is not limited thereto.

According to the above description, in a display device according to the disclosure, a contact area between a bump electrode and a pad electrode may be increased, and thus initial resistance and reliability resistance may be improved.

Further, in a method of manufacturing the display device according to the disclosure, the display device having improved bonding reliability may be manufactured, a low-pressure process may be performed, and thus physical damage to a display panel or an electronic component, which may occur during a bonding process, may be reduced.

Although the description has been made above with reference to an embodiment of the disclosure, it may be understood that those skilled in the art or those having ordinary knowledge in the art may variously modify and change the disclosure without departing from the spirit and technical scope of the disclosure described in the appended claims. Thus, the technical scope of the disclosure is not limited to the detailed description of the specification but should be defined by the appended claims.

What is claimed is:

1. A display panel comprising:
a pixel;
a signal line electrically connected to the pixel; and
a signal pad electrically connected to the signal line,
wherein the signal pad includes:
a first conductive pattern electrically connected to an end portion of the signal line;
a second conductive pattern including a first layer disposed on the first conductive pattern, a second layer disposed on the first layer, and a third layer disposed on the second layer; and
an insulating pattern disposed between the first conductive pattern and the second conductive pattern, and
a groove pattern is formed on an upper surface of the second conductive pattern.

2. The display panel of claim 1, wherein the insulating pattern is disposed inside the first conductive pattern and the second conductive pattern in a plan view.

3. The display panel of claim 1, wherein the insulating pattern includes a lower surface adjacent to the first conductive pattern, an upper surface opposite to the lower surface and spaced apart from the first conductive pattern, and a side surface connected to the upper surface and the lower surface, and
the second conductive pattern covers a portion of the first conductive pattern, in which the insulating pattern is not disposed, the upper surface of the insulating pattern, and the side surface of the insulating pattern.

4. The display panel of claim 3, wherein the groove pattern overlaps the upper surface of the insulating pattern in a plan view.

5. The display panel of claim 1, wherein the groove pattern is formed through the third layer and exposes the second layer.

6. The display panel of claim 1, wherein the second conductive pattern further includes an oxide film disposed on the third layer, and
the groove pattern is formed through the oxide film.

7. The display panel of claim 1, wherein the groove pattern includes at least one groove or at least one crack.

8. The display panel of claim 1, wherein a thickness of the second layer is greater than each of a thickness of the first layer and a thickness of the third layer in a thickness direction.

9. The display panel of claim 1, wherein a conductivity of the second layer is greater than each of a conductivity of the first layer and a conductivity of the third layer.

10. The display panel of claim 1, wherein the insulating pattern includes a polymer.

11. A display device comprising:
a display panel including a signal pad;
an electronic component electrically connected to the display panel; and
an adhesive layer which bonds the display panel and the electronic component together,
wherein the signal pad includes:
a first conductive pattern;
a second conductive pattern in which a groove pattern is formed on an
upper surface of the second conductive pattern and which is disposed on the first conductive pattern; and
an insulating pattern disposed between the first conductive pattern and the second conductive pattern.

12. The display device of claim 11, wherein the second conductive pattern includes a first layer disposed on the first conductive pattern, a second layer disposed on the first layer, and a third layer disposed on the second layer, and
the groove pattern penetrates the third layer and exposes the second layer.

13. The display device of claim 12, wherein the electronic component includes a substrate and a bump electrode disposed on the substrate and protruding in a thickness direction, and
the bump electrode is in contact with the second layer and fills the groove pattern.

14. The display device of claim 13, wherein the second layer exposed by the groove pattern is covered by the bump electrode and is not in contact with the adhesive layer.

15. The display device of claim 11, wherein the insulating pattern is disposed inside the first conductive pattern and the second conductive pattern in a plan view.

16. The display device of claim 11, wherein the insulating pattern includes an upper surface spaced apart from the first conductive pattern, and
the groove pattern overlaps the upper surface of the insulating pattern in a plan view.

17. The display device of claim 11, wherein the insulating pattern includes a polymer.

18. A method of manufacturing a display device, the method comprising:
providing a preliminary signal pad including a first conductive pattern electrically connected to a signal line, a second conductive pattern disposed on the first conductive pattern, and an insulating pattern disposed between the first conductive pattern and the second conductive pattern; and
providing a signal pad by forming a groove pattern on an upper surface of the second conductive pattern.

19. The method of claim 18, wherein the second conductive pattern includes a first layer disposed on the first conductive pattern, a second layer disposed on the first layer, and a third layer disposed on the second layer, and
the groove pattern is formed by a laser or a needle to penetrate the third layer and expose the second layer.

20. The method of claim 19, further comprising:
bonding an electronic component including a bump electrode immediately after the providing of the signal pad,
wherein the bump electrode is bonded to be in contact with the second layer exposed by the groove pattern.
